(19) United States
(12) Patent Application Publication
(10) Pub. No.: US 2017/0024330 A1
(43) Pub. Date: Jan. 26, 2017

(54) Secure Printed Memory

(71) Applicant: Guobiao ZHANG, Corvallis, OR (US)

(72) Inventor: Guobiao ZHANG, Corvallis, OR (US)

(73) Assignee: ChengDu HaiCun IP Technology LLC, ChengDu (CN)

(21) Appl. No.: 15/284,527

(22) Filed: Oct. 3, 2016

Related U.S. Application Data
(63) Continuation of application No. 14/636,367, filed on Mar. 3, 2015.
Application No. 14/636,367 is a continuation-in-part of application No. 13/951,462, filed on Jul. 26, 2013, now abandoned.
Application No. 13/951,462 is a continuation of application No. 13/027,274, filed on Feb. 15, 2011, now abandoned.

(51) Int. Cl. G06F 12/14; G11C 17/16; G11C 17/14; H01L 27/112; H01L 25/065

(52) U.S. Cl. CPC G06F 12/1408; H01L 27/11206; H01L 25/0657; G11C 17/143; G11C 17/16; H01L 2225/06506

(57) ABSTRACT

The present invention discloses a secure printed memory. It comprises a laser-programmable read-only memory (LP-ROM) which stores at least a key. The key is written during manufacturing and different LP-ROMs store different keys. The output of the secure printed memory is encrypted with the key stored in the LP-ROM and is different for different devices. Compromising a single device does not compromise other devices.

### CROSS-REFERENCE TO RELATED APPLICATIONS

This is a continuation of application entitled “Secure Printed Memory”, Ser. No. 14/636,367, filed Mar. 3, 2015, which is a continuation-in-part of application entitled “Secure Three-Dimensional Mask-Programmed Read-Only Memory”, Ser. No. 13/951,462, filed Jul. 26, 2013, which is a continuation of application entitled “Secure Three-Dimensional Mask-Programmed Read-Only Memory”, Ser. No. 13/027,274, filed Feb. 15, 2011.

### BACKGROUND

1. Technical Field of the Invention

The present invention relates to the field of printed memory, and more particularly to semiconductor printed memory.

2. Prior Arts

Printed memory refers to a read-only memory (ROM) whose data are printed. It comprises at least a data-coding layer whose physical pattern represents data. This physical pattern, also referred to as a data-pattern, is transferred from at least a data-template (also known as data-master, data-mask or others) using a printing method during a manufacturing process. Hereinafter, all copies of the printed memory whose data are printed from a same set of data-template(s) are collectively referred to as a printed-memory family.

Printed memory is widely used in optical storage and semiconductor memory. In optical storage, a printed memory is known as an optical printed memory. It is primarily optical disc, e.g. CD, DVD and BD (Blu-ray). In semiconductor memory, a printed memory is known as a semiconductor printed memory. It primarily includes mask-programmed read-only memory (mask-ROM) and imprinted memory (whose content data are printed into the data-coding layer using a nano-imprint method, referring to U.S. patent application Ser. No. 13/602,095, filed Aug. 31, 2012). One notable semiconductor printed memory is three-dimensional printed memory (3D-P, shown in FIG. 6, also referring to U.S. patent application Ser. No. 13/570,216, “Three-Dimensional Printed Memory”, filed Aug. 8, 2012).

As a permanent storage, printed memory is a preferred medium for publication. For copyright protection, the prior-art printed memory encrypts its content by encrypting the data on the data-template(s). For a printed-memory family 100 whose devices (100a, 100b . . . 100z) store the same contents, because all of these devices use a same set of data-template(s) to print content data, they use a same set of encryption key(s) (kₐ for 100a, k_{b} for 100b . . . k_{z} for 100z, with kₐ=k_{b}= . . . =k_{z}) (FIG. 1). Compromising a single device (e.g. 100a) would compromise other devices in the same family 100. In contrast, a writable memory has a better copyright protection. For a writable-memory family 200 whose devices (200a, 200b . . . 200z) store the same contents, because different devices may use different sets of encryption keys ((k*ₐ for 200a, k*_{b} for 200b . . . k*_{z} for 200_{z}, with k*ₐ≠k*_{b}≠ . . . ≠k*_{z}) (FIG. 2), compromising one device does not compromise other devices in the family 200.

### OBJECTS AND ADVANTAGES

It is a principle object of the present invention to improve copyright protection for semiconductor printed memory.

It is a further object of the present invention to protect the contents of other devices in the same family when a single device is compromised.

In accordance with these and other objects of the present invention, a secure printed memory is disclosed.

### SUMMARY OF THE INVENTION

Semiconductor printed memory has a better copyright protection than optical printed memory. Because an optical printed memory is a standalone device and cannot be integrated with an encryption circuit comprising variable encryption keys, its copyright protection is limited. On the other hand, because a semiconductor printed memory can be integrated with an encryption circuit comprising variable encryption keys, its copyright protection can be enhanced to a level like a writable memory (i.e. different devices use different encryption keys).

Accordingly, the present invention discloses a secure printed memory. It comprises a semiconductor printed memory, a laser-programmable read-only memory (LP-ROM) and an encryption circuit. The semiconductor printed memory stores content data, which are same for all devices in a secure printed-memory family. The LP-ROM stores encryption key(s). The key(s) is written during manufacturing and different LP-ROMs store different keys. The encryption circuit encrypts a selected content(s) in the printed memory with a selected key(s) from the LP-ROM. Because different devices in the secure printed-memory family use different encryption keys, compromising a single device does not compromise other devices in the same family.

To further improve copyright protection, all components of a secure printed memory, including the semiconductor printed memory, the LP-ROM and the encryption circuit, are preferably integrated into a single chip. This can prevent the intermediate signals from the semiconductor printed memory and the LP-ROM from being exposed to the external worlds.

To further protect encryption keys, a secure three-dimensional printed memory (3D-P) is disclosed. Its semiconductor printed memory (i.e. 3D-P memory) comprises a plurality of monolithically stacked printed-memory levels. Each printed-memory level comprises at least a 3D-P array, which covers at least a portion of the LP-ROM carrying the encryption keys. Because uncovering the encryption keys requires removal of the 3D-P array that stores the content data, pirating itself defies the purpose of pirating.

### BRIEF DESCRIPTION OF THE DRAWINGS

FIG. 1 illustrates a prior-art printed-memory family and the keys used by respective devices;

FIG. 2 illustrates a prior-art writable-memory family and the keys used by respective devices;

FIG. 3 illustrates a secure printed-memory family and the keys used by respective devices;

FIG. 4 is a block diagram of a preferred secure printed memory;

FIG. 5 is a block diagram of another preferred secure printed memory;

FIG. 6 is a cross-sectional view of a preferred secure 3D-P;

FIG. 7 is a top view of the preferred secure 3D-P, showing the 3D-P memory and its peripheral circuit;

FIGS. 8A-8C illustrate three examples of the secure 3D-P of FIG. 7 with the 3D-P memory not shown, revealing the substrate;

FIG. 9 is a cross-sectional view of a preferred secure printed-memory package;

FIGS. 10AA-10BB illustrate two cases of the secure printed-memory package of FIG. 9.

It should be noted that all the drawings are schematic and not drawn to scale. Relative dimensions and proportions of parts of the device structures in the figures have been shown exaggerated or reduced in size for the sake of clarity and convenience in the drawings. The same reference symbols are generally used to refer to corresponding or similar features in the different embodiments.

### DETAILED DESCRIPTION OF THE PREFERRED EMBODIMENTS

Those of ordinary skills in the art will realize that the following description of the present invention is illustrative only and is not intended to be in any way limiting. Other embodiments of the invention will readily suggest themselves to such skilled persons from an examination of the within disclosure.

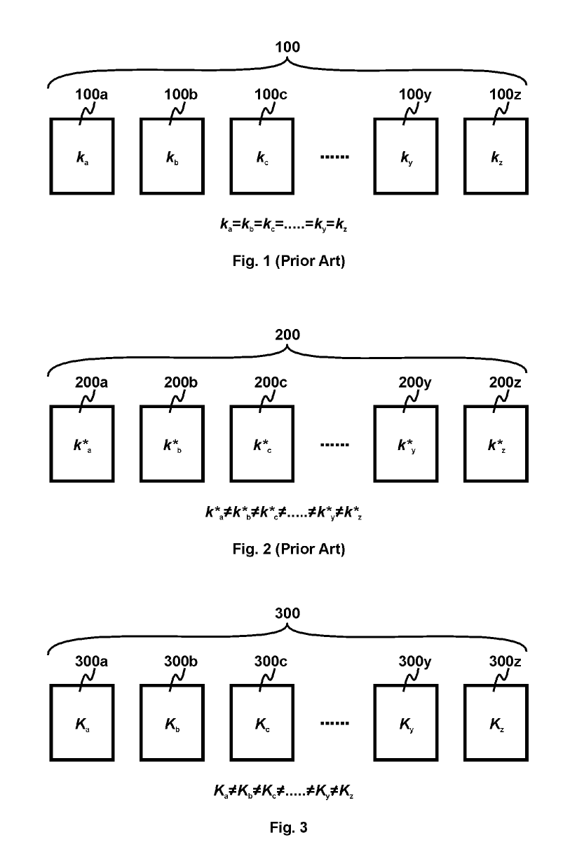

Referring to FIG. 3, a family 300 of secure printed memory is disclosed. It includes a plurality of devices 300a, 300b . . . 300z. Being printed from the same set of data-template(s), these devices have the same data patterns and store the same contents. Integrated with a writable memory storing variable encryption keys, different devices 300a, 300b . . . 300z may use different encryption keys Kₐ, K_{b} . . . K_{z} (with Kₐ≠K_{b}≠ . . . ≠K_{z}) to encrypt their outputs. This level of this copyright protection is same as that of a writable memory (FIG. 2), and is much stronger than that of the prior-art printed memory (FIG. 1).

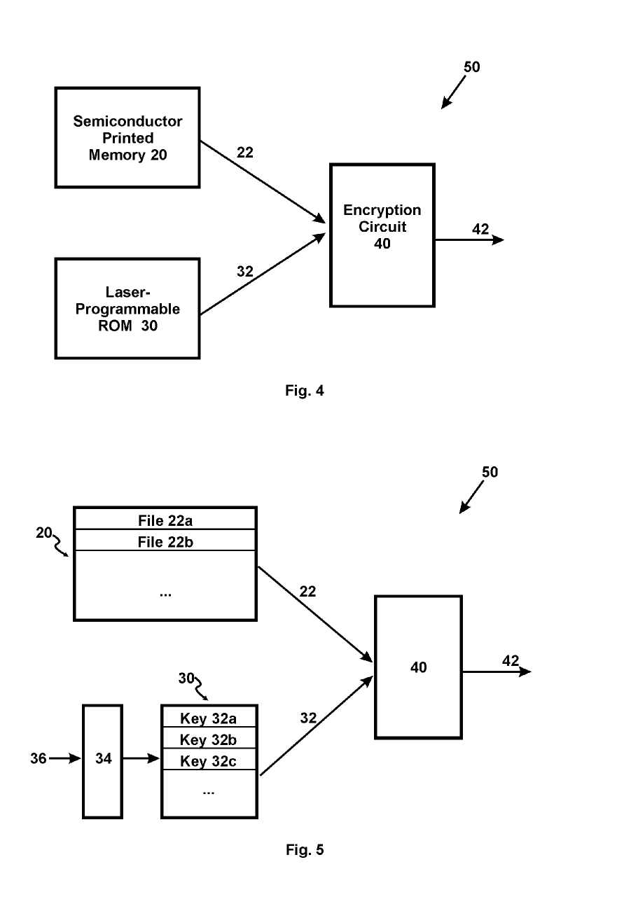

FIG. 4 is a block diagram a preferred secure printed memory 50. It comprises a semiconductor printed memory 20, a laser-programmable read-only memory (LP-ROM) 30 and an encryption circuit 40. The semiconductor printed memory 20 stores contents, including but not limited to: visual contents (e.g. photos, digital maps, movies, television programs, videos, video games), audio contents (e.g. music, songs, audio books), textual contents (e.g. electronic books, or ebooks), software and/or their libraries. Being hard-coded, these content data are same for all devices 300a, 300b . . . 300z in the printed-memory family 300.

The LP-ROM 30 stores variable encryption key(s) 32, which is written during manufacturing. Key(s) 32 are different for different devices 300a, 300b . . . 300z in a same family 300. The encryption circuit 40 encrypts selected content data 22 from the semiconductor printed memory 20 with a selected key 32 from the LP-ROM 30 in such a way that the output 42 of the secure printed memory 50 is encrypted with different keys for different devices. Various encryption algorithms may be employed, e.g. PGP, AES, 3DES, Blowfish. The encryption circuit 40 could also be a data scrambler, which re-arranges content data 22 according to a pattern defined by the key 32. In the mean time, to improve the efficiency of the encryption circuit 40, the content data may be only partially encrypted.

FIG. 5 is a block diagram another preferred secure printed memory 50, which provides file-dependent encryption and time-variant encryption. It further comprises a key-selection logic 34. The semiconductor printed memory 20 stores a plurality of data files (22a, 22b . . . ), while the LP-ROM 30 stores a plurality of keys (32a, 32b, 32c . . . ). The key-selection logic 34 selects key(s) based on an input 36 such as file address, time or other information.

For file-dependent encryption, different data files are encrypted by different keys. For example, the data file 22a is encrypted by the key 32a, while the data file 22b is encrypted by the key 32b . . . . On the other hand, for time-variant encryption, data files are encrypted by different keys during different time periods. For example, the data file 22a is encrypted by the key 32a during a first time period, and encrypted by the key 32c during a second time period . . . . All these features add complexity to breaking into secure printed memory. Besides these techniques, other copyright-enhancing techniques can also be used. For example, different portions of the data file can be encrypted by different keys.

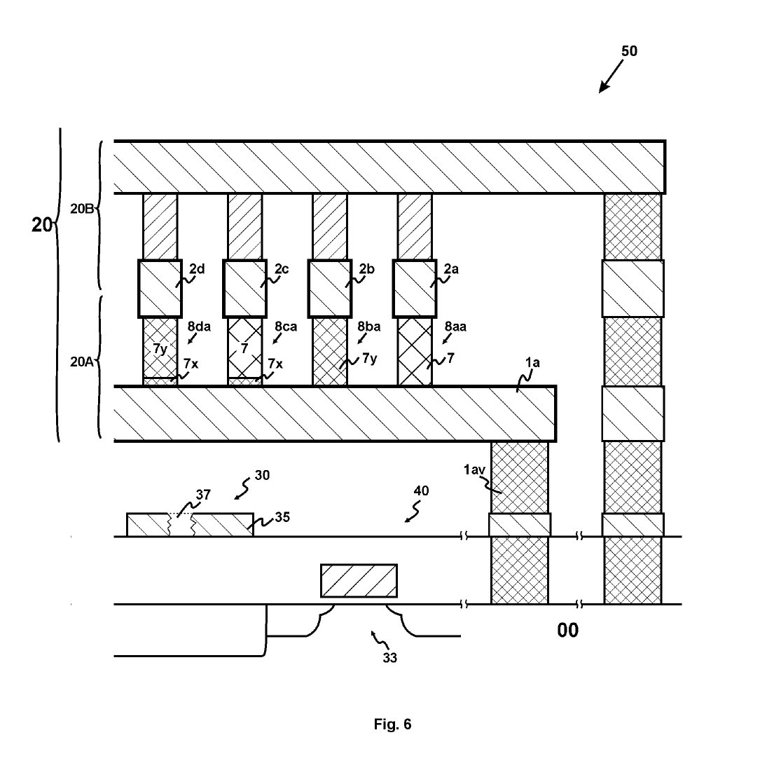

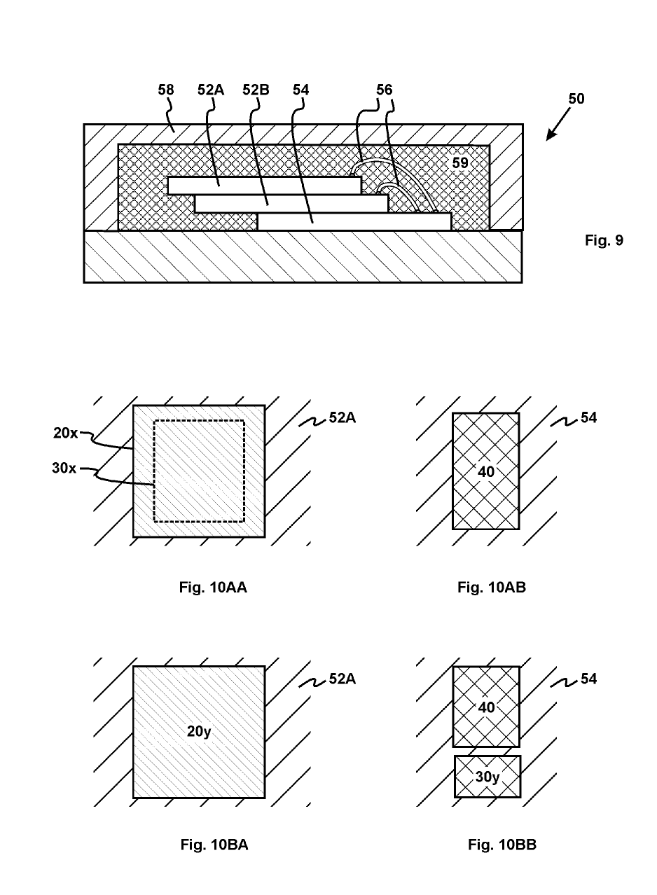

To further improve copyright protection, all components of a secure printed memory 50, including the semiconductor printed memory 20, the LP-ROM 30 and the encryption circuit 40, are preferably integrated in a single chip (FIGS. 6-8C), or in a single protective package (FIG. 9-10BB). Because all data communications are located inside the chip (or, the protective package), the intermediate signals 22, 32 from the semiconductor printed memory 20 and the LP-ROM 30 are not exposed to the external world and are difficult to be tampered with.

Referring now to FIG. 6, a preferred secure 3D-P 50 is disclosed. It comprises a 3D-P memory 20, a LP-ROM 30 and an encryption circuit 40. The 3D-P memory 20 is a monolithic semiconductor memory. It is formed on a semiconductor substrate 00 including transistors 33 and interconnects. The 3D-P memory 20 comprises a plurality of printed-memory levels (20A, 20B . . . ), which are vertically stacked above one another and coupled to the semiconductor substrate 00 through contact vias (1av . . . ). Each printed-memory level 20 further comprises a plurality of printed-memory arrays, with each printed-memory array comprising a plurality of address lines (1a . . . ; 2a-2d . . . ) and memory cells (8aa-8da . . . ). The data stored in memory cells (8aa-8da . . . ) are printed during manufacturing. The printing methods include photolithography (through at least a data-mask) and imprint (with at least a data-template, referring to U.S. patent application Ser. No. 13/602,095, “Imprinted Memory”, filed Aug. 31, 2012). More details on 3D-P can be found in U.S. patent application Ser. No. 13/570,216, “Three-Dimensional Printed Memory”, filed Aug. 8, 2012.

The LP-ROM 30 and the encryption circuit 40 are preferably formed below the 3D-P memory 20. The LP-ROM 30 comprises a laser-programmable fuse 35 and can be programmed during manufacturing, e.g. before the 3D-P memory 20 are formed. By shining a laser beam onto the fuse 35, a gap 37 can be formed in the fuse 35. Existence or absence of the gap 37 indicates the digital state of the LP-ROM cell. LP-ROM 30 is particularly advantageous because it does not require high-voltage programming transistor and incurs minimum process change. Note that, although it is programmed by changing the physical structure of the fuse, LP-ROM is still considered as “soft-coded” because different keys can be programmed into different LP-ROM's.

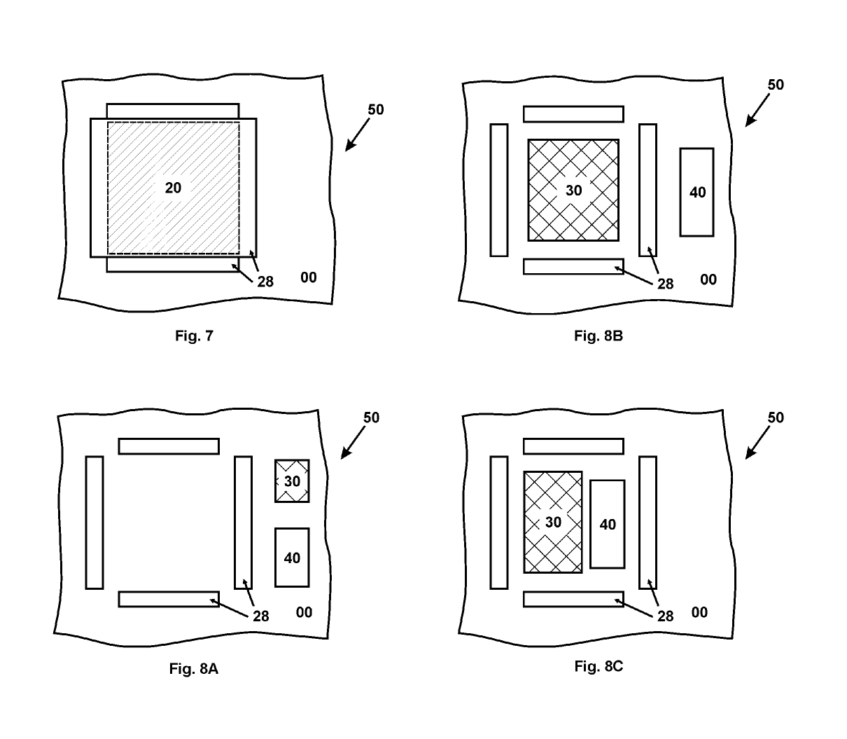

FIG. 7 is a top view of the preferred secure 3D-P 50, showing the 3D-P memory 20 (shaded areas) and its associated peripheral circuit 28. FIGS. 8A-8C illustrate three cases of the secure 3D-P chip with 3D-P memory 20 not shown, revealing the substrate 00. In FIG. 8A, the LP-ROM 30 and the encryption circuit 40 are formed on the substrate 00 but outside the 3D-P memory 20. In FIG. 8B, the LP-ROM 30 is formed underneath the 3D-P memory 20 and covered by the 3D-P array. The encryption circuit 40 is formed outside the 3D-P memory 20 and can be shared. In FIG. 8C, both the LP-ROM 30 and the encryption circuit 40 are formed underneath the 3D-P memory 20 and covered by the 3D-P array. Forming at least a portion of the LP-ROM 30 underneath the 3D-P memory 20 (as in FIGS. 8B-8C) is advantageous because uncovering the encryption keys carried by the LP-ROM 30 requires removal of the 3D-P memory 20, which stores the content data. This defies the purpose of pirating. Note that FIGS. 7-8C are merely representative and are not intended to indicate any actual layout. Layout is a design choice and many configurations are possible.

FIG. 9 is a cross-sectional view of a preferred secure printed-memory package 50. In this preferred embodiment, the semiconductor printed memory 20, the LP-ROM 30 and the encryption circuit 40 are integrated into a single protective package 50. It comprises at least one printed-memory chip 52A, 52B . . . and a support chip 54. All of these chips (52A, 52B . . . , 54) are preferably stacked above one another and coupled to each other through bonding wires 56, then placed in a secure housing 58 filled with protective materials 59 such as molding compound. Because the intermediate signals from the semiconductor printed memory 20 and the LP-ROM 30 are not exposed to the external world and are difficult to be tampered with, this preferred embodiment provides strong copyright protection.

FIGS. 10AA-10BB illustrate two cases of the secure 3D-P package 50 of FIG. 9. In the case of FIGS. 10AA-10AB, the 3D-P chip 52A comprises at least one 3D-P array 20x (shaded area) and at least one writable-memory array 30x. The writable-memory array 30x is located underneath the 3D-P array 20x (FIG. 10AA). In the meantime, the support chip 54 comprises the encryption circuit 40 (FIG. 10AB). In the case of FIGS. 10BA-10BB, the 3D-P chip 52A comprises at least one 3D-P array 20y (FIG. 10BA), while the support chip 54 comprises at least one writable-memory array 30y and the encryption circuit 40 (FIG. 10BB).

While illustrative embodiments have been shown and described, it would be apparent to those skilled in the art that many more modifications than that have been mentioned above are possible without departing from the inventive concepts set forth therein. The invention, therefore, is not to be limited except in the spirit of the appended claims.

What is claimed is:

1. A secure printed memory in a secure printed-memory family, comprising:
a semiconductor substrate;
a printed memory formed on said semiconductor substrate for storing content data, wherein said content data are same for all devices in said secure printed-memory family;
a laser-programmable read-only-memory (LP-ROM) formed on said semiconductor substrate for storing at least a key, wherein said key is written during manufacturing and different LP-ROMs store different keys;
an encryption circuit formed on said semiconductor substrate for encrypting said content data in said printed memory with said key in said LP-ROM;
wherein the output of said secure printed memory is the encrypted content data from said encryption circuit and is different for different devices in said secure printed-memory family.

2. The secure printed memory according to claim 1, wherein said printed memory is a mask-programmed read-only memory (mask-ROM).

3. The secure printed memory according to claim 1, wherein said printed memory is an imprinted memory.

4. The secure printed memory according to claim 1, wherein said LP-ROM stores a plurality of keys.

5. The secure printed memory according to claim 4, wherein said secure printed memory further comprises a key-selection logic for selecting at least a key from said plurality of keys.

6. The secure printed memory according to claim 5, wherein said encryption circuit provides file-dependent encryption.

7. The secure printed memory according to claim 6, wherein said key-selection logic selects said key base on file.

8. The secure printed memory according to claim 5, wherein said encryption circuit provides time-variant encryption.

9. The secure printed memory according to claim 8, wherein said key-selection logic selects said key base on time.

10. A secure three-dimensional printed memory (3D-P) in a secure 3D-P family, comprising:
a semiconductor substrate;
at least a printed-memory level stacked above and coupled to said semiconductor substrate, said printed-memory level storing content data, wherein said content data are same for all devices in said 3D-P family;
a laser-programmable read-only-memory (LP-ROM) between said printed-memory level and said semiconductor substrate, said LP-ROM storing at least a key, wherein said key is written during manufacturing and different LP-ROMs store different keys;
an encryption circuit formed on said semiconductor substrate for encrypting said content data in said printed-memory level with said key in said LP-ROM;
wherein the output of said secure printed memory is the encrypted content data from said encryption circuit and is different for different devices in said secure 3D-P family.

11. The secure 3D-P according to claim 10, wherein said printed-memory level comprises a printed-memory array.

12. The secure 3D-P according to claim 11, wherein said printed-memory array covers at least a portion of said LP-ROM.

13. The secure 3D-P according to claim 10, wherein said 3D-P is a three-dimensional mask-programmed read-only memory (3D-MPROM).

14. The secure 3D-P according to claim 10, wherein said 3D-P is a three-dimensional imprinted memory.

15. The secure 3D-P according to claim 10, wherein said LP-ROM stores a plurality of keys.

16. The secure 3D-P according to claim 15, wherein said secure printed memory further comprises a key-selection logic for selecting at least a key from said plurality of keys.

17. The secure 3D-P according to claim 16, wherein said encryption circuit provides file-dependent encryption.

18. The secure 3D-P according to claim 17, wherein said key-selection logic selects said key base on file.

19. The secure 3D-P according to claim 16, wherein said encryption circuit provides time-variant encryption.

20. The secure 3D-P according to claim 19, wherein said key-selection logic selects said key base on time.
